(19) United States
(12) Patent Application Publication
(10) Pub. No.: US 2017/0221871 A1
(43) Pub. Date: Aug. 3, 2017

(54) SYSTEMS AND METHODS FOR MANUFACTURING ELECTRONIC DEVICES

(71) Applicant: Octavo Systems LLC, Austin, TX (US)

(72) Inventors: Gregory Michael Sheridan, Houston, TX (US); Gene Alan Frantz, Sugar Land, TX (US); Masood Murtuza, Sugar Land, TX (US); Shankar Jayaraman Panchavati, Missouri City, TX (US)

(73) Assignee: Octavo Systems LLC, Austin, TX (US)

(21) Appl. No.: 15/420,873

(22) Filed: Jan. 31, 2017

Related U.S. Application Data
(60) Provisional application No. 62/289,783, filed on Feb. 1, 2016.

(51) Int. Cl. H01L 25/00; H01L 25/065; G05B 19/418; H01L 23/544

(52) U.S. Cl. CPC H01L 25/50; H01L 23/544; H01L 25/0655; G05B 19/4188; H01L 2223/5444; G05B 2219/45031

(57) ABSTRACT

Systems and processes for flexible and/or low volume product manufacture, including cost effective ways to manufacture low volume system level devices. In one aspect, this disclosure enables the manufacture of a plurality of System in Package (SiP) devices. In one aspect, the devices include one or more of an optical and electrical identifier, corresponding to substrates and/or product designs. The identifiers can be used in the assembly of the devices.

### TECHNICAL FIELD

Aspects of this disclosure relate to systems and methods for manufacturing electronic devices, including packaged devices, such as System in Package (SiP) devices.

### BACKGROUND

Improvements in integrated circuit (IC) and semiconductor technology have fostered rapid product growth in a number of areas, such as the Internet of Things (IoT), Big Data, and Cloud Computing. Additionally, IC and semiconductor technology improvements have led to cost reductions for consumer products, medical products, and industrial products. These products typically have components that need to be integrated together, including processor, memories, power management elements, and interfaces to the external world and other products.

The manufacturing process for electronic devices, including IC and semiconductor products and devices, is typically a sequence of steps. Although the specific steps may vary based on the specific product, the process may include some form of design, planning, and/or setup, after which the products are assembled on a production line. Current design, fabrication, and manufacturing and assembly processes and their associated production lines are typically set up to handle one product or device at a time, and in high volumes. However, there remains a need for systems and processes for flexible and/or low volume product manufacture, including cost effective ways to manufacture low volume system level devices.

### SUMMARY

According to some embodiments, standard IC manufacturing and assembly line machines found in conventional production lines are programmed to use device identifiers and employed to incorporate a complete system into a standard IC or semiconductor package to create System in Package (SiP) devices.

According to some embodiments, a method of manufacturing a plurality of SiP devices on a production line system is provided. The method includes assembling a first device of the plurality of SiP devices. Assembling the first device may include arranging a first plurality of components on a first substrate according to a first design, wherein the first substrate has a first optical identifier on its surface, and creating a first electrical identifier related to the first design. The method further includes assembling a second device of the plurality of SiP devices. Assembling the second device may include arranging a second plurality of components on a second substrate according to a second, different design, wherein the second substrate has a second optical identifier on its surface, and creating a second electrical identifier related to the second design. In some instances, creating the first electrical identifier comprises placing one or more resistive elements, capacitive elements, or wire bonds on the first substrate, while creating the second electrical identifier comprises placing one or more resistive elements, capacitive elements, or wire bonds on the second substrate. Similarly, at least one of the first and second optical identifier can be formed by one or more resistive elements, capacitive elements, or wire bonds. The identifiers may be used, for instance, in one or more testing procedures for the devices.

In certain aspects, assembling the first and second devices can occur in a single production run.

According to some embodiments, a SiP device is provided. The SiP device may include a substrate and a plurality of components arranged on the substrate to define an electrical identifier corresponding to the SiP device design. The substrate may also have an optical identifier for the substrate, located on a surface of the substrate. The device may further include a matrix of connectors on the substrate to allow for programmable interconnections between the plurality of components attached to the substrate. One or more of the components may be, for example, SiP devices themselves.

According to some embodiments, a method of manufacturing a plurality of SiP devices is provided. The method includes setting up a production line system for a first design of a first SiP device of the plurality of SiP devices, as well as setting up the production line system for a second design of a second SiP device of the plurality of SiP devices. The setup is such that the first and second designs are both set up in the production line system. The method further includes loading a first set of components and a second set of components together on the production line system, where the first set of components and the second set of components are selected from a single group of components. The method further includes loading a first substrate and a second substrate on the production line system, and assembling the first and second SiP devices based on the first and second designs using the production line system. The first and second SiP devices can be assembled in a single production run. In this example, the first design can use at least one component from the first set of components and the first substrate, while the second design uses at least one component from the second set of components and the second substrate. In certain aspects, the first and second substrate each include one or more optical identifiers and the assembling is based at least in part on one or more of the optical identifiers. Similarly, the first design can correspond to an electrical identifier of the first SiP device and the second design can correspond to an electrical identifier of the second SiP device.

According to some embodiments, a production line system for manufacturing a plurality of SiP devices is provided. The production line system may include one or more memories, production line storage equipment, and one or more processors. The memories may be used for storing at least a first design of a first of the plurality of SiP devices and a second design of a second of the plurality of SiP devices, such that the first and second designs are both contained in the memories of the production line system. In this example, the production line storage equipment is configured to store a set of preselected components on the production line system and to store first and second substrates on the production line system. In certain aspects, the first design uses at least one component from the set of preselected components and the first substrate, and the second design uses at least one component from the set of preselected components and the second substrate. The one or more processors are configured to control one or more machines of the production line system to assemble the first and second SiP devices in a single production run. Additionally, the processors may be further configured to read one or more optical identifiers on each of the first and second substrate, and control the production line to assemble the first and second SiP devices based at least in part on the optical identifiers. Similarly, the processors may be further configured read one or more electrical identifiers corresponding to the first and second designs and control the production line to assemble the first and second SiP devices according to the electrical identifiers.

According to some embodiments, a method for manufacturing a plurality of SiP devices selected from a preselected set of SiP device designs is provided. The method includes setting up a production line system for the plurality of SiP device designs, where each of the plurality of designs contains components and substrates selected from a preselected set of components and a preselected set of substrates. The method further includes loading the preselected set of components onto equipment of the production line system based on the selected SiP device designs, and loading the preselected set of substrates onto the equipment of the production line system based on the selected SiP device designs. The method further includes assembling the selected components on the selected substrates using the production line system to create a first number of SiP devices according to a first of the plurality of SiP device designs and a second number of SiP devices according to a second of the plurality of SiP device designs. In certain aspects, at least one of the first and second numbers of devices is one. Additionally, one or more of the substrates may be for a family of devices. The method may also include programming one or more pieces of equipment in the production line system to automatically adjust its settings to perform unique activities needed for each substrate based on an identifier for each of the substrates in conjunction with the design, and do so when the substrate is loaded on each piece of equipment.

According to some embodiments, the disclosed SiP devices may include a substrate populated with passive and active components interconnected to make a functional system, and incorporated into a package. In certain aspects, the way in which systems are designed is changed so that multiple different system designs can flow sequentially down the same assembly and test lines without modifying all the machines in the entire production line for each new design. The processes of certain embodiments create the appropriate software instructions for each assembly and test machine in the production line to allow assembly and test to occur on the different products or devices without interruption to the overall production flow.

According to some embodiments, the disclosed processes are used to eliminate or reduce the amount of set up for a conventional production line. By using, for example, a standard substrate design, the same substrate can be used for a family of standard SiPs. The substrate employed in a unique SiP design may include a unique identification number (ID) for that design. This ID can be utilized by the production line system to eliminate the need for a new set up for each system using the same standard substrate. Similarly, according to some embodiments, a super-set of constituent die may be presented at a die pick and place machine, which has a mechanism that uses the ID to determine which sub-set of devices to pick. Such an arrangement may reduce, or even eliminate change over time to load wafers or die on the pick and place machine. Additionally, embodiments using a standard substrate size can eliminate the need for unique substrate handling systems in surface mount technology (SMT), die attach, wire bond, and mold as all the potential component locations are the same for each family of devices using the same standard substrate. By utilizing a full complement (i.e., fully populated) ball array in a BGA package, the need for unique tooling for the ball placement machine or tool can also be avoided.

According to some embodiments, the disclosed processes and systems: (a) use a substrate ID to uniquely select programs, instructions or directives used by manufacturing and assembly machines in an integrated circuit or semiconductor production line; (b) use standard substrates all having preselected fixed and compatible sizes to eliminate multiple setups for each machine in an integrated circuit production line; (c) use generic families of standard substrate designs to reduce the number of different substrates in inventory; (d) present to the production machines a super-set of active and passive components to eliminate the need to load new parts for each SiP design; and (e) use the same solder paste, die attach, wire bond, mold compound and ball materials to avoid the need to change these items for each SiP product design.

The above and other aspects and embodiments are described below with reference to the accompanying drawings.

### BRIEF DESCRIPTION OF THE DRAWINGS

The accompanying drawings, which are incorporated herein and form part of the specification, illustrate various embodiments.

FIG. 1 is an illustration of steps for the design, fabrication, and manufacturing of a device using a production line, according to some embodiments.

FIG. 2 is an illustration of a production line system according to some embodiments.

FIG. 3 is a flow chart illustrating a process according to some embodiments.

FIG. 4 is a flow chart illustrating a process according to some embodiments.

FIG. 5 is a flow chart illustrating a process according to some embodiments.

FIG. 6 is a flow chart illustrating a process according to some embodiments.

FIG. 7 is a flow chart illustrating a process according to some embodiments.

FIG. 8 is a flow chart illustrating a process according to some embodiments.

FIG. 9 is a flow chart illustrating a process according to some embodiments.

FIG. 10A, FIG. 10B, and FIG. 10C are illustrations of a device according to some embodiments.

FIG. 11 is a flow chart illustrating a process according to some embodiments.

FIG. 12 is a flow chart illustrating a process according to some embodiments.

FIG. 13 is a flow chart illustrating a process according to some embodiments.

FIG. 14 is a flow chart illustrating a process according to some embodiments.

FIG. 15 is a flow chart illustrating a process according to some embodiments.

### DETAILED DESCRIPTION

There is an increasing need for semiconductor products for use in consumer electronics, automotive applications, oil and gas applications, medical applications, industrial applications, and aerospace applications, among others. Additionally, there is also the Internet of Things (IoT), Cloud Computing and Big Data applications, in addition to other smart applications that may require one or more microprocessors, memories, power management elements, communication components, and sensors. Accordingly, many applications currently require one or more integrated circuit (IC) devices to meet design needs.

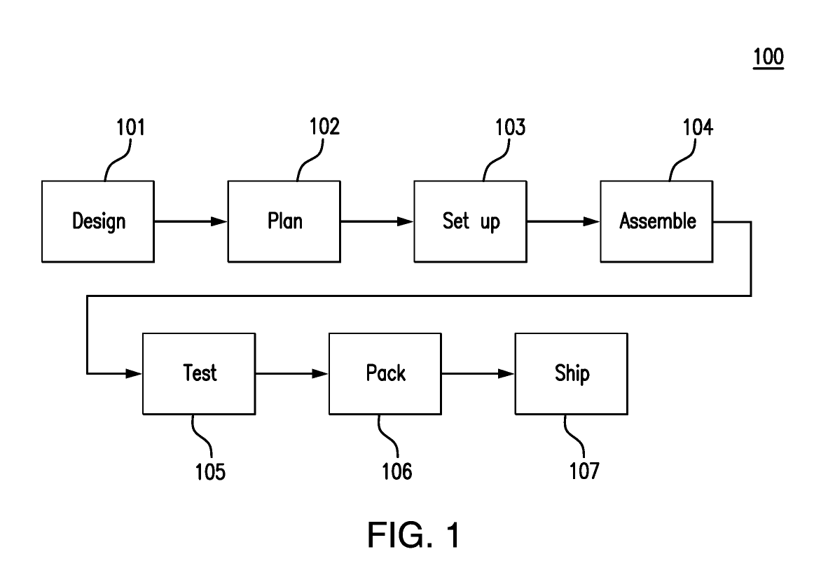

The overall manufacturing process for a semiconductor product or device, including integrated devices, may be broken down, at a high level, into the following set of steps: design (101), plan (102), set up (103), assemble (104), test (105), pack (106), and ship (107). These steps are illustrated in the production flow 100 of FIG. 1. Each process step in flow 100, for example in a production line system, may require several different pieces of specialized equipment to perform the unique steps in an overall design, fabrication, manufacturing and assembly process. Presently, for each different end-product or device manufactured on the production line, the equipment needed for each process step needs to be adjusted or programmed for the unique properties and components associated with that product or device. But once the production line is set up for that product or device, the production line is capable of producing high volumes of that product or device at a relatively fixed and minimum unit cost.

However, if a second product or device is to be manufactured using the same production line as the first product or device, then the equipment used to make the first product or device and the process steps used must be modified to deal only with the second product or device. This change in process steps starts with the initial design step and then may require changes for each following step. As production of a new device currently requires significant process changes, the focus on driving down integrated circuit and system product cost has left out a significant part of the market, such as the market for system level products or devices and the integration of such systems. That means, effectively, low volume product opportunities are left without an economic integration path. Accordingly, there is a need for cost effective ways to flexibly manufacture low volume system level devices.

By way of example, a market for a set of semiconductor product could be categorized by the size of the company, for instance, in three segments: (1) big vertical companies; (2) companies that are large enough to buy directly from a vendor; and (3) the “long tail” companies, many of which is may be too small to get the attention of a vendor, and thus, must buy through distribution channels. Often, only the big vertical companies can take advantage of System on Chip (SoC) technology, while the long tail customers may be relegated to using chips on board. For lower volume companies, the integration might occur on a Printed Circuit Board (or Chips on Board—“COB”, also called PCB), while for high volume companies the integration could occur on a System on Chip (SoC). However, in certain applications, neither the PCB nor the SoC solution are optimal for an integration of a system having multiple components. In some instances, the optimal solution for integration of a complex system is accomplished by using a System in Package (SiP), where diverse components can be integrated together at a more cost efficient manner than either using a PCB or SoC. In some cases, an SoC, once designed may become a SubSystem on a Chip (SSOC) of a larger system that may be integrated into a SiP.

System in Package (SiP) devices are currently used in the semiconductor industry to assemble multiple integrated circuits, other devices and passive components in one package. SiPs are attractive because they allow miniaturization of microelectronic systems from a printed circuit board tens of square cm in size to typically a single package approximately 5 square cm or less. SiPs enable integration of devices with diverse device fabrication technologies such as digital, analog, memories and other devices and components such as discrete circuits, devices, sensors, power management and other SIPs that are otherwise impossible or impractical to integrate in a single silicon circuit like an ASIC or SoC. These other discrete circuits used in a SiP may include non-silicon based circuits.

In some instances, due to their low volume opportunities, long tail companies must use a PCB to integrate systems. Although they may have an advantage of a lower upfront cost (NRE), such companies are cost disadvantaged once in production due to their low volume. Whereas the big vertical companies may pay a large NRE to create an SoC, for example, over the life of the end product the higher volume at a lower cost rapidly compensates for the high initial the NRE. Accordingly, an SiP solution is an interesting middle road for both long tail companies and the big vertical companies, as the NRE is low enough for the long tail company and reduces the cost of the components enough to help the big vertical companies.

Referring now to FIG. 1, FIG. 1 illustrates a production process 100 according to some embodiments. In the example of process 100, the first step is the actual design of the device or product 101. Once the device is designed, a plan 102 is developed for where, how, and/or when the device will be manufactured. The plan step may also identify the components and the design of a circuit board for the system (sometimes referred to as a mother board) and may include ordering those components and/or board from various suppliers to enable the device to be built. Upon completion of the plan step, the set up step 103 for the production line is where all of the machines used in the production line are readied and programmed as needed. Once readied, the assemble step 104 takes place. After the assemble step is completed, the devices may sequentially pass through the test step 105, pack step 106, and ship step 107. These steps may be performed, for instance, in connection with a production line system 200.

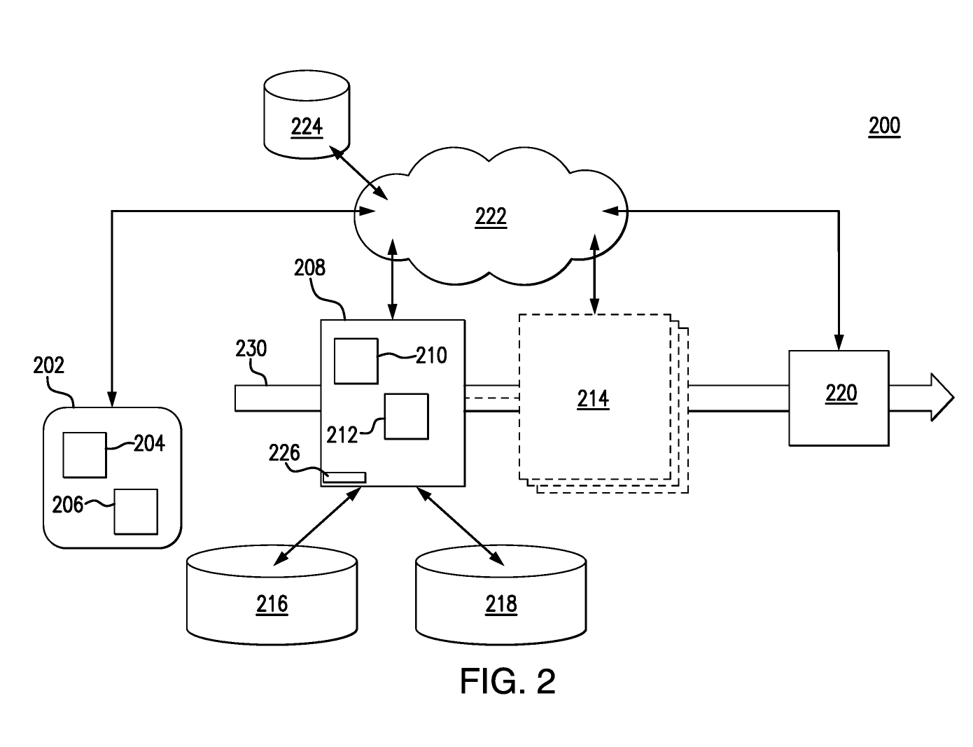

Referring now to FIG. 2, FIG. 2 is an illustration of a production line system 200 according to some embodiments. The system can be used to produce electronic devices, such as SiP devices, according to flow 230. The system may include a production machine 208. The system can also include additional machines 214. The machines may include, for instance, die placement machines, including Pick and Place machines, wire bonding machines, and molding devices. In the example of FIG. 2, the system 200 further includes storage equipment. For instance, the machines 208, 214 may be coupled to substrate storage 216 and component storage 218.

Following assembly, for instance by machines 208, 214, the system may be configured to perform one or more packaging and testing steps at stage 220. Testing may include modular testing apparatuses, including handlers and bins for products. According to certain aspects, one or more components of system 200 may be in communication with each other via network 222, which can have its own storage 224. By way of example, test equipment could be in communication with one or more machines 208, 214 or other connected equipment or machines to identify the appropriate test protocol for a given device. Additionally, the production line system may have a controller module 202. The controller 202, or a controller of a machine 208, may identify a substrate from 216 and put it on the production line. Similarly, components from storage 218 can be placed on the substrate on the production line by one or more machines 208, 214. The populated substrates are then passed down the production line on flow 230 to additional machines (such as 214) to further assemble the device. According to some embodiments, one or more of the machines and/or controller 202 include memory 204, 210 and one or more processors 206, 212. As such, the production line system includes memory and processors. In some embodiments, the machines 208, 214 include detectors 226 for reading optical and/or electrical identifiers of devices under process. For instance, they may detect the identifier of a substrate being used on system 200. Such information may communicated amongst system 200 components via network 222.

FIG. 2 schematically illustrates, in terms of a number of functional modules, including the components of the production line system 200. The modules, including processors 206, 212, may include a data processing system (DPS), which may include one or more processors (e.g., a general purpose microprocessor and/or one or more other processors, such as an application specific integrated circuit (ASIC), field-programmable gate arrays (FPGAs), and the like). The various components of system 200 may also include transmitters and receivers, including network interfaces, to communicate via network 222. Such communications may be wired or wireless. According to some embodiments, the memories 204, 210 may include one or more non-volatile storage devices and/or one or more volatile storage devices (e.g., random access memory (RAM)). In some embodiments, the system 200 may be programmed to perform steps described herein (e.g., steps described herein with reference to the flow charts of FIGS. 1, 3-9, and 11-15), including through a non-transitory computer readable medium, such as, but not limited, to magnetic media (e.g., a hard disk), optical media (e.g., a DVD), memory devices (e.g., random access memory), and the like. In other embodiments, the system 200 may be configured to perform steps described herein without the need for code. Hence, the features of the embodiments described herein may be implemented in hardware and/or software.

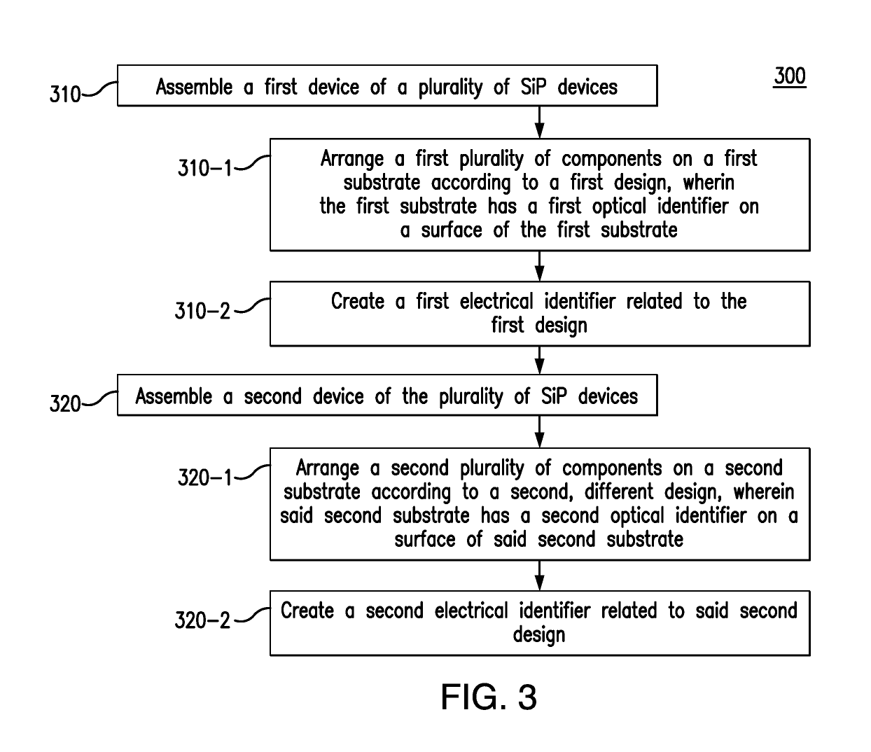

Referring now to FIG. 3, FIG. 3 is a flow chart illustrating a process 300 for manufacturing a plurality of SiP devices, according to some embodiments, performed by a production line system. For example, process 300 could be performed by system 200.

Process 300 may begin, for example, with step 310, where a first device of the plurality of SiP devices is assembled. According some embodiments, the assembly of step 310 includes two sub-steps, 310-1 and 310-2. In step 310-1, a first plurality of components is arranged on a first substrate according to a first design. In certain aspects, the first substrate has a first optical identifier on a surface of said first substrate. In step 310-2, a first electrical identifier is created. This electrical identifier may be related, for example, to the first design.

In step 320, a second device of the plurality of SiP devices is assembled. According some embodiments, the assembly of step 320 includes two sub-steps, 320-1 and 320-2. In step 320-1, a second plurality of components is arranged on a second substrate according to a second design. A production line system, such as system 200, may import the first and second designs into one or more of its memories. In certain aspects, the second substrate has a second optical identifier on a surface of said second substrate. In step 320-2, a second electrical identifier is created. This identifier may be related, for example, to the second design. In some embodiments, the first imported design refers to the first optical identifier and the first electrical identifier, while the second imported design refers to the second optical identifier and the second electrical identifier. Also, and according to some embodiments, the first and second devices can occur in a single production run. Thus, different SiPs having different designs and/or substrates, and possibly using different components, can be manufactured together without need to re-tool or otherwise adjust the production line system.

The assembly of steps 310 and 320 may be performed, for instance, using one or more of machines 208 and 214. For instance, assembly may include the placement of one or more die or other components by the machines. The identifiers may be read by the detector(s) 226. The design used in flow 300 may be stored, for instance, in one or more of memories 204 and 210, and controlled by one or more of processors 206, 212. The first and second substrates may be stored in storage 216, while the components may be retrieved from storage 218, for instance, by machine 208.

In some embodiments, the first and second substrates of steps 310 and 320 may have identical layouts to each other. For instance, the substrates may have the same layer, wiring, and connection arrangements. In this example, the substrates may share the same optical identifiers. Alternatively, in some embodiments, the substrates may have differing layouts and use different optical identifiers. Whether the layouts are the same or not, the substrates may both be part of the same substrate panel for processing. That is, according to some embodiments, a panel used by the production line system, such as system 200, may include either all identical substrates, or an arrangement of differing substrates. In certain aspects, the optical identifiers can be used by the production line system to identify each of the substrates of the panel. The panel may be stored, for example, in storage 216 of system 200.

According to some embodiments, step 310-2 creating the first electrical identifier includes placing one or more resistive elements, capacitive elements, or wire bonds on the first substrate. Similarly, step 320-2 can include placing one or more resistive elements, capacitive elements, or wire bonds on the second substrate. In certain aspects, the optical identifier of the substrates may be formed by one or more resistive elements, capacitive elements, or wire bonds. The optical identifier may be, for example, numerical values. In certain aspects, the numerical values and/or component arrangements may be readable by the production line system, such as system 200. Additionally, the production line system may be configured to adjust one or more settings of one or more machines, such as machines 208, 214 in the production line system 200 based at least in part on the first or second optical identifier. The production line system may also adjust one or more settings of one or more machines in the production line system based at least in part on the first or second electrical identifier. In this respect, the specific operations of the production line system for a particular run and/or set of designs may be controlled through use of the identifiers.

In certain aspects, the process 300 may include additional steps. The steps may include, for instance, loading the first and second components together on the production line system, where the first set of components and the second components are selected from a single group of components. Also, the first and second substrates may be loaded on the production line system, where each of the first and said second substrates is a common substrate for one or more families of devices. The loading steps may occur, for instance, before step 310. Additionally, the process 300 may include testing of the first device based on one or more of the first optical identifier and the first electrical identifier, as well as testing the second device based on one or more of the second optical identifier and the second electrical identifier.

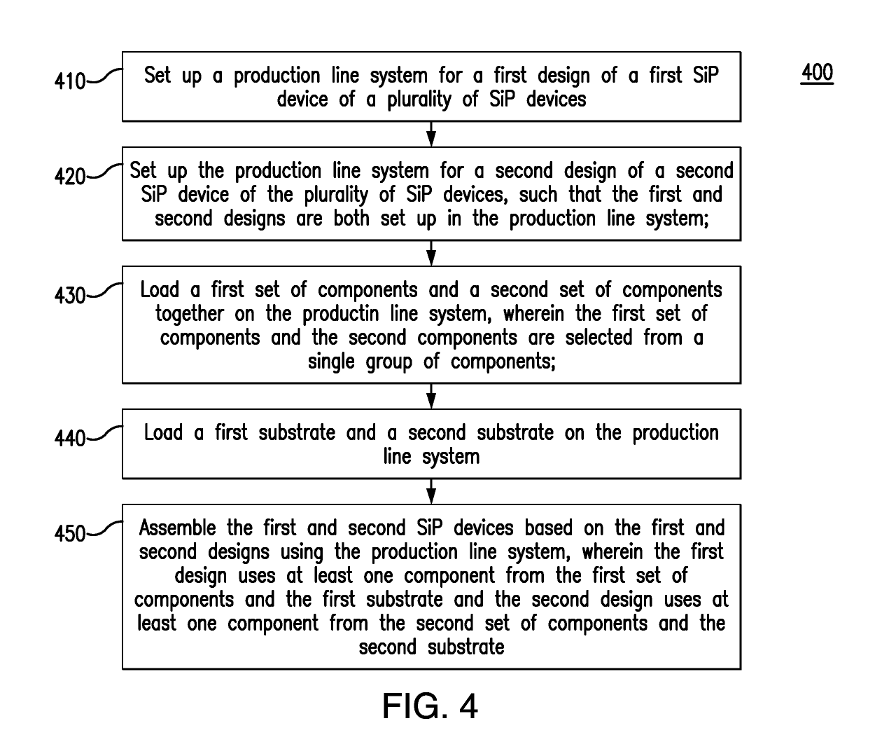

Referring now to FIG. 4, FIG. 4 is a flow chart illustrating a process 400 for manufacturing a plurality of SiP devices, according to some embodiments. Process 400 may be performed, for example, in connection with production line system 200.

Process 400 may begin, for example, with step 410. In step 410, a production line system, such as system 200, is set up for a first design of a first SiP device of the plurality of SiP devices. This setup may include, for example setting up one or more machines 208, 214, such as the Pick and Place machines with the correct SMT (and other) components, the die placement machines with the correct wafers or die, the automated testing equipment 220 with the correct combined test program(s), and setting up any wire bonding, molding and ball attach machines 208, 214. In step 420, the same production line system is set up for a second design of a second SiP device of the plurality of SiP devices, such that the first and second designs are both set up in the production line system. Thus, according to some embodiments, a production line system, such as system 200, can be setup simultaneously to produce two different devices, even if the devices use different substrates and components.

In step 430, a first set of components and a second set of components are loaded together on the production line system. According to some embodiments, the first set of components and the second components are selected from a single group of components. For instance, the first set of components may be an alternative version of the second set of components. By way of example, the first set of components may be Op-amps having first characteristics, while the second set is Op-amps have second characteristics. Also by way of example, the Op-amps are preselected so that only certain types and values are available in the sets of components. In some embodiments, at least one of the first and second sets of components is a set of fabricated SiPs. These components may be loaded into storage 218.

In step 440, a first substrate and a second substrate are loaded on the production line system. According to some embodiments, the first and second substrates may be on a common panel for processing. The first and second substrates may also have an identical layout. The substrates may be loaded, for instance, into storage 216.

In step 450, the first and second SiP devices are assembled based on the first and second designs. In certain aspects, the first design uses at least one component from the first set of components and the first substrate, while the second design uses at least one component from the second set of components and the second substrate. The assembly of the first and second SiP devices may occur, for example, during a single production run. According to some embodiments, the first and second substrates each include one or more optical identifiers and the assembling is based at least in part on the identifiers. Additionally, the first design can correspond to an electrical identifier of the first SiP device, and the second design can correspond to an electrical identifier of the second SiP device.

In some embodiments, each of the first and second substrates contains a matrix of connector pads for programmable interconnections between components. In this example, assembling 450 the first and second SiP devices may also include: (i) interconnecting a plurality of matrix pads on the first substrate according to the first design; and (ii) interconnecting a plurality of matrix pads on the second substrate according to the second design. The interconnecting may performed, for instance, by a wire bond machine 208.

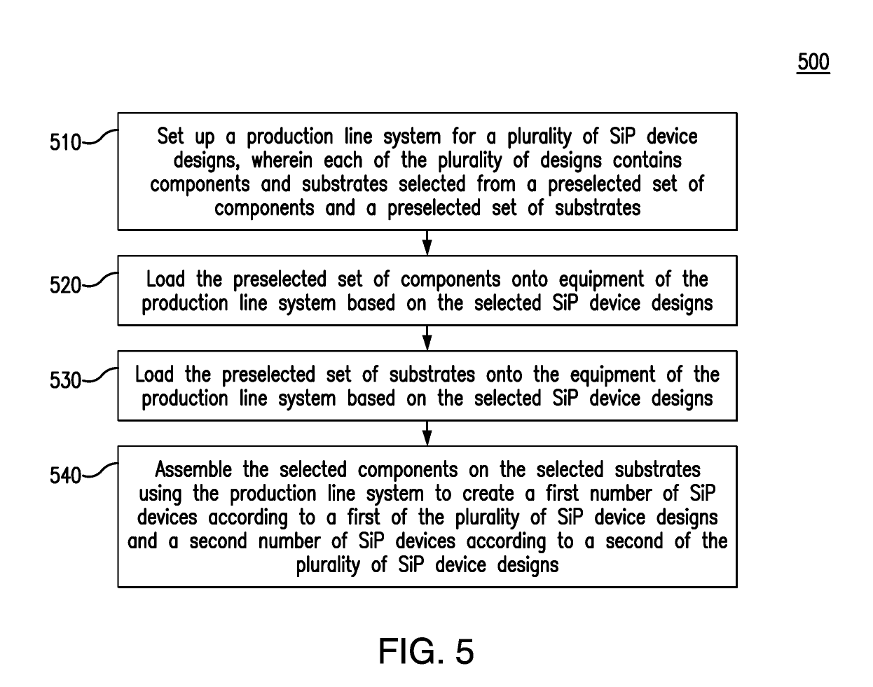

Referring now to FIG. 5, FIG. 5 is a flow chart illustrating a process 500 for manufacturing a plurality of SiP devices, according to some embodiments. Process 500 may be performed, for example, in connection with production line system 200.

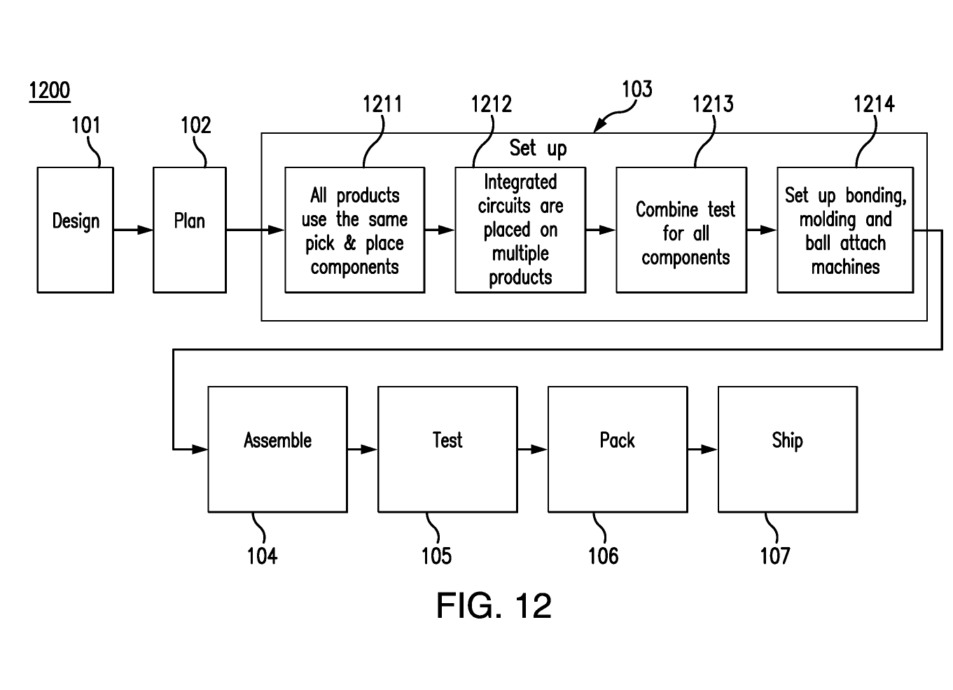

Process 500 may begin, for example, with step 510. Step 510 includes setting up a production line system, such as system 200, for a plurality of SiP device designs. Set up 510 may include, for instance, one or more processes discussed in connection with FIG. 12. According to some embodiments, each of the plurality of designs contains components and substrates selected from a preselected set of components and a preselected set of substrates. In certain aspects, the plurality of SiP device designs may use only components and substrates from the sets of preselected components and substrates.

In step 520, the preselected set of components is loaded onto equipment of the production line system based on the selected SiP device designs. Components may be loaded, for example, into storage 216 of system 200.

In step 530, the preselected set of substrates is loaded onto the equipment of the production line system based on the selected SiP device designs, such as from substrate storage 216. According to some embodiments, each substrate in the preselected set of substrates is for a family of devices. Additionally, the production line system can include one or more machines configured to receive substrates of a standard size, and each substrate of the preselected set of substrates can have standard and fixed dimensions.

In step 540, the selected components are assembled on the selected substrates using the production line system to create a first number of SiP devices according to a first of the plurality of SiP device designs. A second number of SiP devices are created according to a second of the plurality of SiP device designs. According to some embodiments, at least one of the first and second numbers of created devices is one. Thus, according to certain aspects of the provided methods, a batch size of as small as one may be accomplished for a particular SiP device design. In further embodiments, the plurality of SiP device designs each have a unique identifier. This identifier can correspond to one or more optical or electrical identifiers of SiP devices assembled according to the designs.

According to some embodiments, process 500 may further include programming one or more pieces of equipment in said production line system, such as machines 208, 214 to automatically adjust its settings to perform unique activities needed for each substrate based on said unique identifier for each of said substrates in conjunction with said design when said substrate is loaded on each said piece of equipment. This may be performed, for instance, as part of setup step 510.

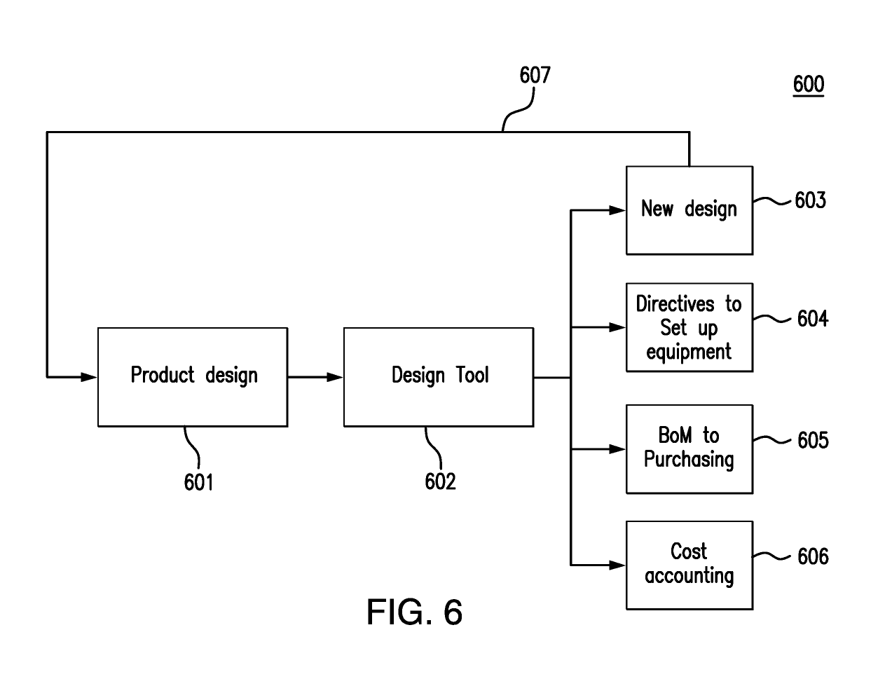

Referring now to FIG. 6, FIG. 6 depicts detailed steps 600 for the interaction between a design step and a set up step for a production line system. For example, 600 may illustrate steps corresponding to 101-103 of FIG. 1, and in connection with production line system 200. In some respects, steps 600 describe the relationship between a product design 601 and a design tool 602, as well as outputs from these two activities. The outputs include, for example, the directives to set up the production line equipment for the assemble step 604, the final bill of material (BoM) 605, so that the correct components can be purchased and create the cost accounting data 606. One other potential output is information for a new design 603, which may either be a cost reduced version, a new family member in the product line, and/or a next generation product according to some embodiments. Information in connection with steps 600 may be stored, for instance, in one or more of memories 204, 210, and 224.

According to flow 600 of an example process, this information is returned to the product design 607. In certain aspects, the design process actions 601 and 602 can include: (1) developing a functional design of the device; and (2) identifying the individual components which will be inserted during the assembly process by the assembler using a production flow. The resulting design details may be returned to the owner of the device for signoff before production is planned and started.

The system design team responsible for the product (or device) design 601, may for example, do the design of the system and verify its functionality. A particular functionality may be verified in one or more ways, including by a computer simulation, by creating a bread-board version of the device, by prototyping using either a PCB (Printed Circuit Board) or SoM (System on Module), or by altering an existing version of the device assuming the product has already been in production prior to a process. The verified design may then be entered into an assembly process design tool 602.

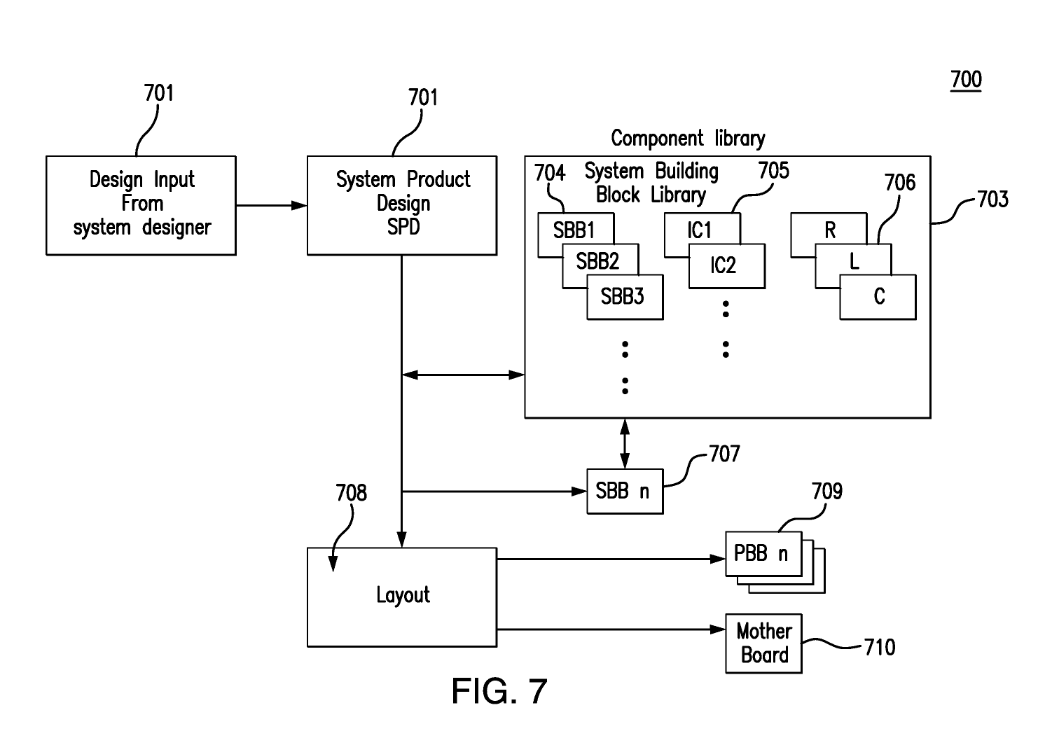

Referring now to FIG. 7, FIG. 7 describes details regarding a design process 700 in accordance with some embodiments. As shown in FIG. 7, multiple systems can be designed with a single production flow created for them. For example, the design tool 702 may accept as an input one or more documents or pieces of data or information from the product design process 701. Several pre-design functions of the design tool may be created and placed in a component library 703; a library of System Building Blocks (SBB) 704 (Standard SIP substrates) already created from previous designs and available for use in a design for the production line (these substrates could be for a family of devices based on, for example, but not limited to, processors, analog interfaces, memories, power management, sensors, and actuators); a library of available ICs 705 in die-form (like A/Ds or D/As, processors, OpAmps, memories, etc.) that may be used during the assembly process; and a library of passive or other types of components 706 available for use during the assembly process. Information may be stored, for instance, in one or more of memories 204, 210, and 224 and communicated via network 222. In some embodiments, each substrate may contain a matrix of conductive pads located on the surface of the substrate to allow for programmable interconnections between components attached to the substrate in addition to the normal fixed substrate interconnections.

According to certain embodiments, the passive and other components are only a preselected subset of all possible values for each type of component. For example, instead of having capacitors of any value for use in a design, the library of capacitors will have preselected values, for example, but not limited to, 1 microfarad, 0.1 microfarad, 0.001 microfarad, etc. Similarly, for resistors and other types of passive components and ICs, only limited preselected values would be available for use in the design.

The system design input from the system designer may be matched with a library of standard substrates (SBBs) 704, with each SBB type capable of being used for a family of subsystems. In this matching, the system design is parsed into portions that may correspond to one or more of the family of circuits that may be available on an SBB. For example, if the product requires multiple analog interface devices, the predetermined library of SBBs is compared to the desired system design's requirements. If an appropriate analogue SBB is found, then the portion of the schematic, net-list and BoM for a subsystem corresponding to the system design portion that can made using that particular SBB can be assigned to the specific particular matching SBB. A Product Building Block (PBB) may then be assigned, which is the standard substrate populated with the BoM components connected in accordance with the netlist. A PBB can be a SBB populated with components for one of a family of subsystems or for a partial section of a system. In certain aspects, each substrate SBB may contain a matrix of conductive pads located on the surface of the substrate to allow for programmable interconnections between components attached to the substrate in addition to the normal fixed substrate interconnections.

According to some embodiments, not all system product designs (SPD) need to be integrated into a single SiP. In many cases there are logical groupings of components in a system design that can make common building blocks that can be integrated into a Building Block SiP (BBSiP). For example, in an analog interface system, there may be a common need for a BBSiP of Operational Amplifiers. This BBSiP could have n OpAmps on it with m passive locations for each of the n OpAmps for a substrate type dedicated to OpAmp circuit families. Many different OpAmp signal conditioning circuits BBSiPs could be configured on the same SBB. Each SBB substrate may contain a matrix of conductive pads located on the surface of the substrate to allow for programmable interconnections between components attached to the substrate in addition to the normal fixed substrate interconnections. The same can be done with a customized A/D and D/A BBSiP, a processor system BBSiP or a sensor and actuator BBSiP. Although this example refers to OpAmps, it may be applied to other passive and active components, including other SiPs.

Referring to FIG. 7, in certain embodiments, if there is no match in the library of SBBs for portions of the product design, either a new SBB 707 is proposed and laid out 708 to accommodate that portion of the design, or those components are not accepted as part of the production flow and the system designer is responsible for including them in the mother board design 710 which will later have the completed PBBs 709 attached to complete the final system design.

Moreover, a unique substrate identification number (ID) can be assigned to each SBB. This ID can be used throughout the manufacturing and assembly process. This ID may be permanently included on the substrate by different methods, such as for example, but not limited to, laser scribing, or giving a binary or analog code using a detectable array. The binary or analog code may be associated with certain pins of the packaged substrate so that it can be read after the substrate has been encapsulated. The ID may also be stored by a microprocessor, microcomputer or non-volatile memory located on the substrate, if available on the substrate. This ID may be a visually readable identifier, such as a numeric value.

To manage the process of multiple devices being assembled on the same substrate, a device ID or PBB ID can be added to the substrate and used to identify the devices built for each device in the production line. In some embodiments, a design ID will be added to the substrate ID to form either a device (which may have multiple PBBs in it) or PBB ID to determine, for example, the components to be placed on the substrate, what test routine will be used for final test, what part number will be put on the packaged device and where it will be shipped, etc. Unique device (or product) identification numbers may then be used by equipment in a production line system, including machines 208, 214 to select and use the program needed by that equipment for that board and its associated components. A PBB may be a standalone device.

For example, the PBB ID may be defined in two steps such that its ID will be both optically and electrically detectable. The SBB ID can be created as part of the initial substrate layout. For instance, the SBB ID can have n bits in its ID depending on how many different substrates are on a panel. By way of example, but not by way of limitation, the ID may be determined by a set of package pins or balls selectively attached to a voltage rail or left open (or tied to a second voltage rail or to ground). When the pins are electrically read by a piece of equipment, each will either be held at the voltage rail or be open (or at a second voltage rail or ground). In the case it is left open, using a pull down (or pull up) resistor on the equipment reading the ID, the output will either be at the rail voltage or at ground, assuming the pull down resistor is tied to ground.

The second part of the ID can be created at a first assembly step, for instance, where the SMD devices are attached to the substrate. In some embodiments, resistors, for example, are attached to a second set of m pins and a voltage rail. These resistors can be the basis of the SBB ID portion of the overall design ID where the full device ID is a combination of the n bit SBB and m unique bits for a unique design ID. In this example, and using the same method as used for the SBB ID, the equipment reading the ID will see either the voltage of the rail or ground based on the pull down resistor, or may optically scan and see any resistors and their placements. For some embodiments, the SBB ID and design ID marking method needs to be done such that the IDs can be both optically and electrically detected. Using various values of resistance for the m ID bits gives more options for the design ID by providing more voltage levels than just the rail voltage or ground. For some embodiments, the final device may be a single PBB and in this instance the design ID and PBB ID are the same and the device ID is a combination of the SBB and design ID. For other embodiments, where the final device contains a plurality of PBBs, the device ID will be unique.

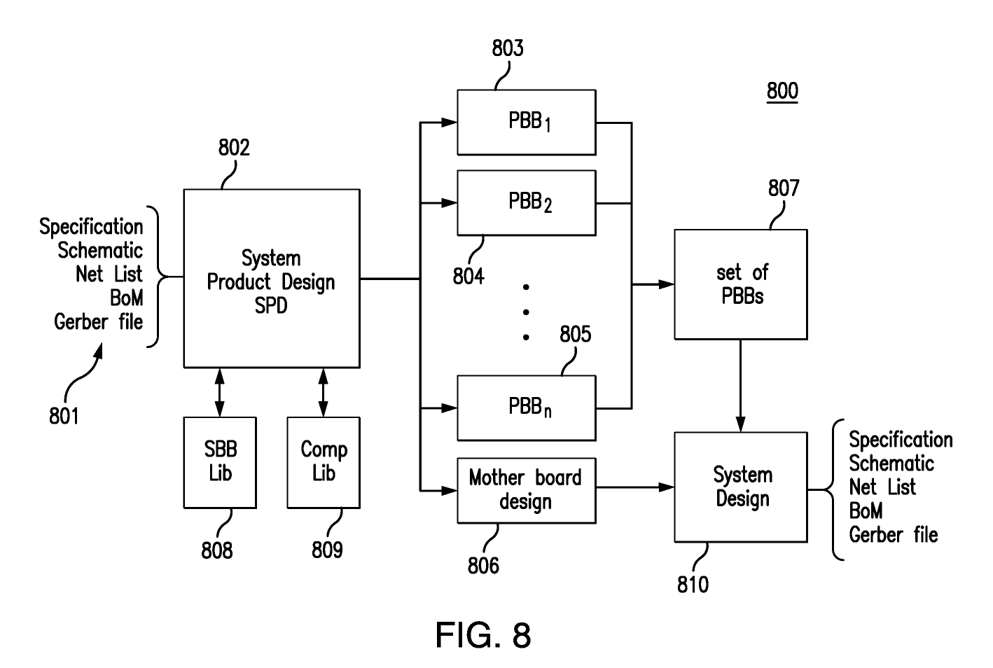

Referring now to FIG. 8, the detailed process 800 to create a set of Product Building Blocks (PBB) from the input of a system design, according to some embodiments, is provided. More particularly, FIG. 8 further depicts how the System Product Design tool 802 (for instance, as described with respect to FIG. 7) can create a complete system design 810 with many PBBs 803, 804 805 and a mother board 806. The System Product Design (SPD) tool 802 uses the inputs from the system design items 801, the SBB library 808 and the Component Library 809 to create the PBBs 803, 804, 805 and mother board 807. In certain aspects, the SBB Library 808 of FIG. 8 can correspond to the SBB portion 704 of the Component library 703, and the component library 809 can correspond to the IC 705 and passives 706 portions of the Component library 703 in FIG. 7. Similarly, the PBBs 803, 804, 805 can correspond to the PBB n portion 709 of FIG. 7, and the mother board design 806 to the mother board 710 of FIG. 7. Although the system design 810 is illustrated as having a variety of outputs, the BoM may be the aggregate BoM for all the PBBs used in the design, as well as any components to be mounted on the motherboard. Similarly, the gerber file may be the file for the mother board 806.

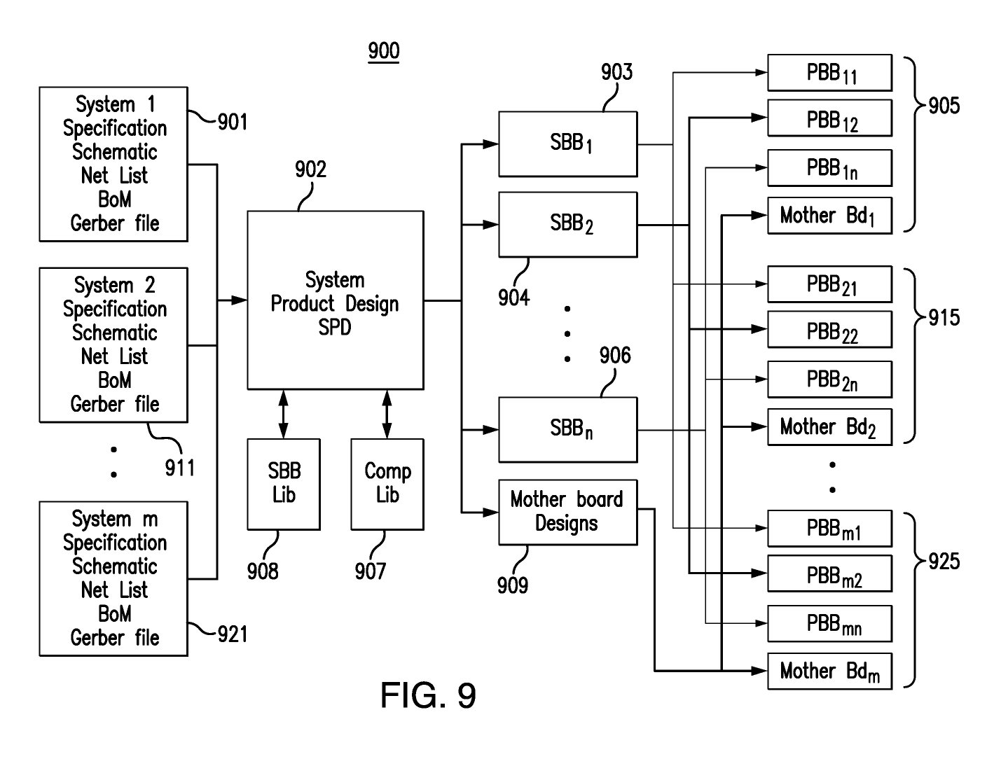

Referring now to FIG. 9, FIG. 9 depicts the process 900 for using one PBB to create portions of a system for multiple different systems designs, according to some embodiments. More particularly, FIG. 9 depicts how the System Product Design (SPD) 902 can be utilized to design many systems 905, 915, 925 using the same set of PBBs 903, 904, 906. In this example, the SPD tool 902 takes as its inputs the system design information from three different system designs 901, 911, 921, the SBB library 908 and the Component library 907 to generate a unique set of SIPs using at least one of the PBBs in each of the SiP systems 905, 915 and 925. In certain aspects, the SBB Library 908 corresponds to the SBB portion 704 of the Component library 703, and the component library 907 corresponds to the IC 705 and passives 706 portions of the Component library 703 in FIG. 7. In a similar manner, the PBBs 903, 904, 906 correspond to the PBB n portion 709 of FIG. 7, and the mother board designs 909 corresponds to the mother board 710 of FIG. 7. The system designs 905, 915, 925 are illustrated as having a variety of PBBS and mother boards in this example. The BoM for all these systems could be the aggregate of the BoMs for all the PBBs used in the designs, as well as any components to be mounted on the motherboards. Similarly, although not depicted, each system design could include gerber files for the mother board of that system.

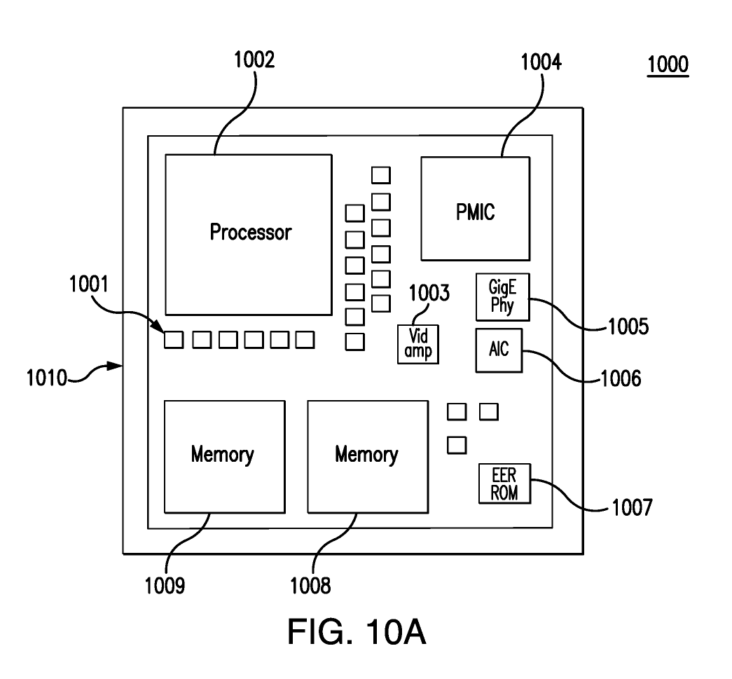

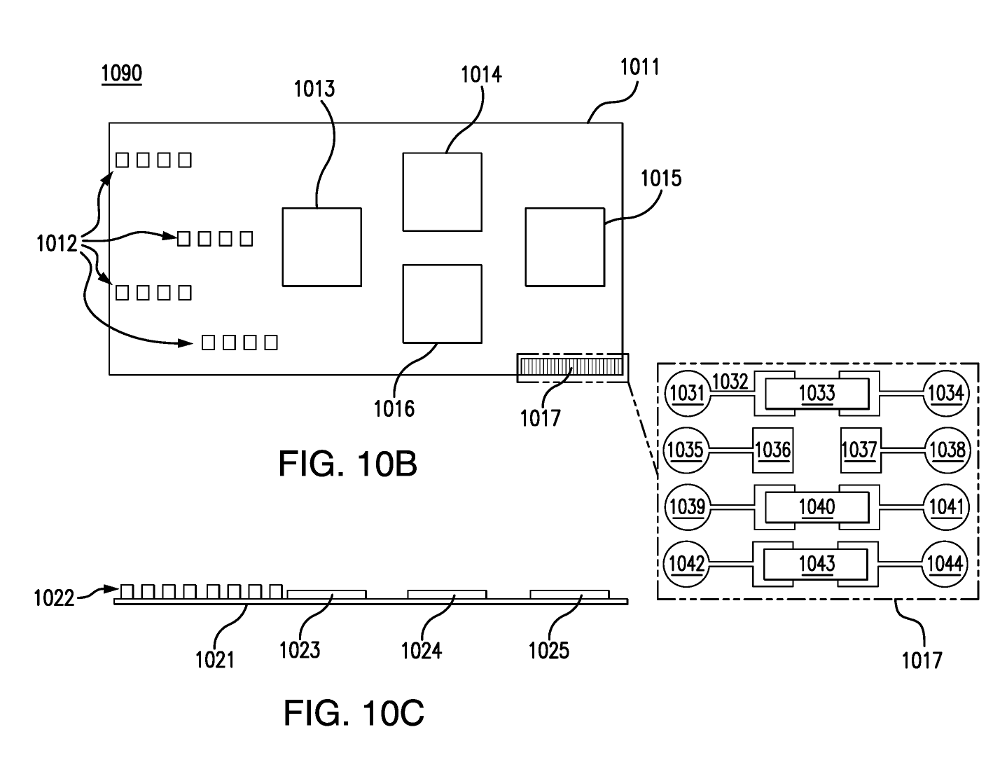

In the examples of FIG. 8 and FIG. 9, one system design with many PBBs, and one PBB being used in multiple systems, respectively, is depicted. According to some embodiments, the system design then would consist of a mother board, for instance as shown in FIG. 10B, with one or more BBSiPs or PBBs. With the complex portions of the system contained in the BBSiPs, the substrate (mother board) could be simplified with fewer conductive layers, a smaller footprint and lower overall cost. As depicted in FIG. 8, the design tool 801 may accept one or more inputs, including a device schematic, a device Net List, one or more PCB Gerber files, bills of material (BOMs), specification(s) of the device, and any other documents, data, or information needed to describe the device.

Referring now to FIG. 10A, a top view of an example of a Product Building block (PBB) 1000 according to some embodiments is depicted. In this example the PBB has multiple components integrated on the SBB 1010. The components are passives 1001, processor 1002, Video Amplifier 1003, Power Management Integrated Circuit 1004, Gigabit Ethernet Phy 1005, Analog Interface Chip 1006, EEPROM 1007 and two Memory devices 1008, 1009. Other examples of a PBB may be either more or less complex. Although not separately depicted, PBB 1000 has an SBB and PBB identifier that is both optically and electrically readable, similar to item 1017 of FIG. 10B.

Referring now to FIG. 10B, a top view of a complete system 1090 made using a mother board 1011 with four PBBs 1013, 1014, 1015, 1016 and associated discrete components 1012 according to some embodiments is depicted. Similarly, FIG. 10C depicts a side view of the mother board 1011, which includes the mother board side view 1021, the PBBs 1023, 1024, 1025 and the associated discrete components 1022. System 1090 also includes an optical identifier 1017 for the substrate 1011.

FIG. 10B also depicts an expanded view of one embodiment of how optical identifier 1017 may be manufactured using resistors 1033, 1040, 1043 or other components that may be attached to pads, similar to pads 1036, 1037, which may in turn may be attached to balls 1031, 1034, 1035, 1038 for external pins or balls. In this manner, the optical identifier also may be measured electrically using the external pins or balls of the device 1090. Again, by way of example, but not by way of limitation, the ID may be determined by a set of package pins or balls selectively attached to a voltage rail or left open (or tied to a second voltage rail or to ground). When the pins are electrically read by a piece of equipment, each will either be held at the voltage rail or be open (or at a second voltage rail or ground). In the case it is left open, using a pull down (or pull up) resistor on the equipment reading the ID, the output will either be at the rail voltage or at ground, assuming the pull down resistor is tied to ground.

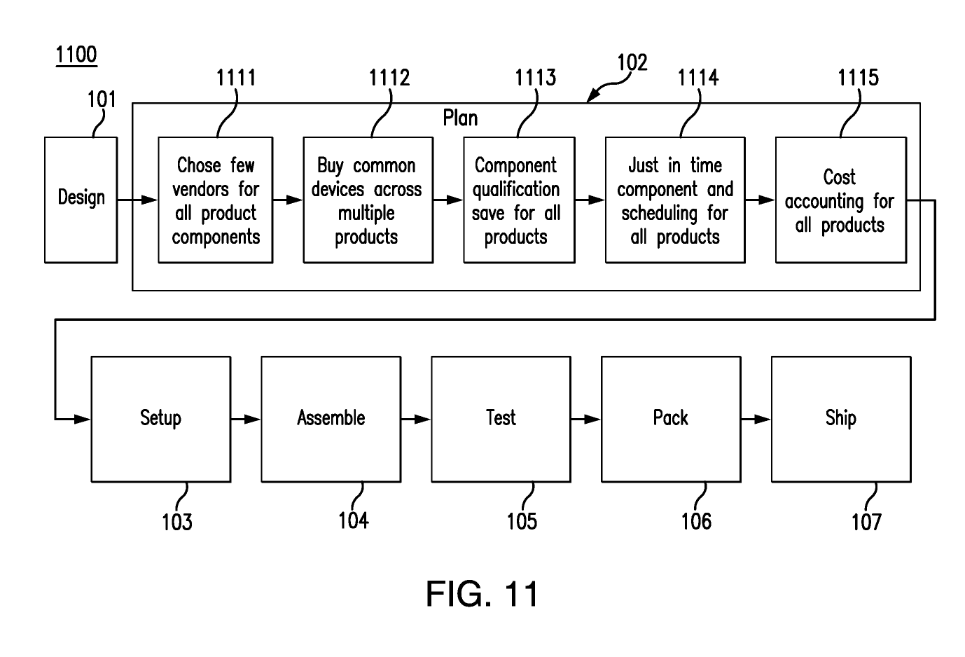

According to some embodiments, once an “assembly-ready” design has been completed, it can be returned to a system designer for approval. Once approved, the design can be parsed as needed to, for instance, set up the production line, purchase the components and do the cost accounting. Referring now to FIG. 11, a plan step 1100 according to some embodiments is provided. In this example, the output of the Design process 101 shown in FIG. 1 is at least a BoM required for each SiP to be used either as a standalone system or to be part of a given final product to be manufactured. Once all of the necessary components are identified for all of the other designs being aggregated into the assembly flow 104, a minimum set of vendors is chosen 1111 and the components for all of the SiPs to be assembled are bought 1112. The components and substrate are then received, inspected for damage or other properties and stored 1113, 1114.

In some embodiments, several different system designs, e.g., PBBs, may be designed using the same identical substrate. In certain aspects, multiple such substrates provide options for many different types of systems. Thus, cost accounting 1115 could be simplified as it is concerned about the aggregate production flow rather than each of the unique SiPs which constitute the aggregate production flow. In certain aspects, the aggregate flow is concerned with the total number of capacitors of one fixed value that are used by all the SiPs in the aggregate flow, rather than dealing with the unique number of capacitors for each individual SiP design. The output of the planning process 102 is the information necessary for the setup 103 of the assembly 104, test 105, pack 106 and ship 107 processes to follow.

In some embodiments, the planning process depicted in FIG. 11 uses common BoM items having preselected values and uses of a common set of substrates across different products, rather than having the new BOM items and the required substrate change for every new product while selecting the vendors 1111 and ordering the components 1112. The passive and other components can be a preselected subset of all possible values for the component. For example, instead of having capacitors of any value for use in the design, the library of capacitors will have preselected values, like for example, but not limited to, 1 microfarad, 0.1 microfarad, 0.001 microfarad, etc. Similarly for resistors and other types of passive components only limited preselected values would be available for use in a design. Similarly for active devices, like OpAmps, A/Ds, processors, and memories, limited preselected die for these devices would be selected and available for use in a design. Thus, the original system designers may be constrained to use components from a selected set of components having preselected electrical values while providing the same functionality that their specific product or device requires. This constraint may be reduced by limiting the set of components to be those actually needed for the aggregation of device designs to be produced in a manufacturing batch. If n system devices are included in the manufacturing batch (made up of the n system devices) the limitation could be to the n system device needs rather than a broader set of system devices.

In certain aspects, a new supply chain is used that appears as a single and unchanging supplier regardless of the actual constituent supplier base through a system of vendor qualification 1113. For example, one major supplier can be identified who acts as a de facto supplier for all the required components of the BoM (the aggregation of all of the system devices included in the manufacturing batch). It is the responsibility of the de facto supplier to ensure that quality components are provided Just in Time (JIT) 1114 for all builds of required device designs by negotiating with the sub vendors/suppliers at a pre-negotiated price. When compared to methods where much time is lost in the planning process due to time spent in qualifying, meeting with, talking, negotiating with the various suppliers involved for each component in each of the system product BoMs, embodiments provide efficiency advantages. Again, the aggregate flow may be more concerned with the total number of capacitors of one fixed value that are used by all the SiPs in the aggregate flow, rather than dealing with the unique number of capacitors for each individual SiP design and negotiating for each individual SiP design's BoM one at a time. For example, each individual SiP can have its own compliment of components that make up its BoM; each of those components will have a specification and quality requirements. Each component will need to be purchased in the volume needed for its design. If there are ten such SiP designs that are part of the aggregate flow, then there are potentially ten separate meetings to buy these components for the ten designs. If all the designs use the same fixed value capacitor, then the step to buy this capacitor can be aggregated to one meeting and one purchase order to buy this same capacitor in a quantity needed for all ten designs. Similarly for any quality requirements, there is only one vendor qualification needed and not ten individual qualifications.

Referring now to FIG. 12, a set up step 1200 according to some embodiments is depicted. From FIG. 1, the set up step 1200 for SiP assembly involves collecting the needed information for the various production machines from the Planning process 102 based on the individual BoMs from the design process 101. This information, for each substrate (SBB) or device ID is used, for example, to set up the Pick and Place machines with the correct SMT components 1211, the die placement machines with the correct wafers or die 1212, the ATE with the correct combined test program 1213, and setting up the wire bonding, molding and ball attach machines 1214. Once the Set up process has been completed the next steps of assembly 104, test 105, pack 106 and ship 107 can proceed.

By using a standard substrate design, the same substrate can be used for multiple SIPs. This eliminates need for a new set up for each new system design or PBB that uses a standard substrate. This is in contrast to a set up where each design or SIP utilizes a different substrate, a different set of active and passive devices, different die attach, wire bond, and molding materials, and where each SIP requires a change in the set up step for all the equipment in the manufacturing line. Similarly, by always presenting a super-set of constituent die at the die pick and place machine and having a mechanism to determine which sub-set of devices to pick reduces or eliminates change over time to load wafers or die on the pick and place machine. Using standard substrate panel sizes eliminates the need for unique substrate handling systems in surface mount technology (SMT), die attach, wire bond, mold as all the component locations are the same. By utilizing a full complement (fully populated) ball array in a BGA package the need for a unique ball placement tool is avoided. If only a portion of the balls are utilized then a special ball placement tool is needed to be able to attach only that portion of balls. And if the portion changes, then the tool attaching them may also have to change.

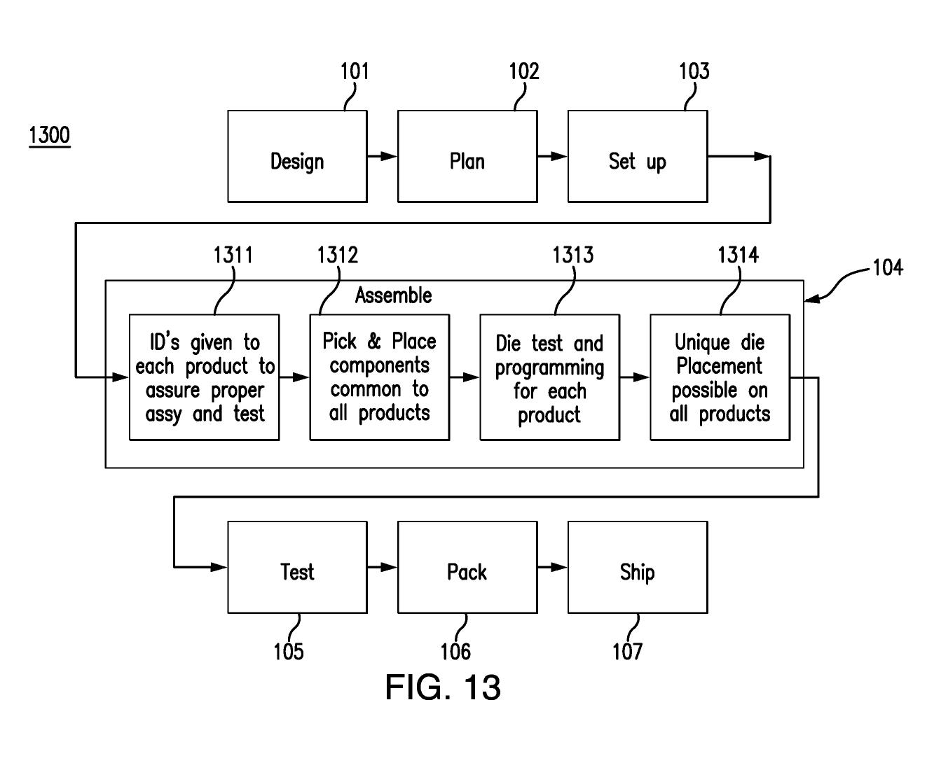

Referring now to FIG. 13, an assemble step 1300 according to some embodiments is depicted. As shown in FIG. 1, the assemble step 104 for a SiP assembly, just as it is for integrated circuit assembly, follows the setup process 103 in which each associated production line machine is programmed to populate the panel of substrates 1312, with the appropriate active and passive components 1314 based on the device ID 1311 associated with the substrate in the panel. In this example, any testing or programming of an integrated circuit die needed during the assembly process is done at 1313, which although not currently performed, may be performed in the future. For example, but not limited to, programming may be performed by bond wire placement, laser etching, changing EEPROM bits with a laser, etc. Assembly can be determined by the planning process 102 based on the individual BoMs from the design process 101. Once the assemble process has been completed the next steps of test 105, pack 106 and ship 107 can proceed.

According to some embodiments, the disclosed methods and system use a unique substrate or device ID 1311 readable throughout the assembly process to determine all required pick and place actions from the super-set of components, both active and passive, available for attachment to a substrate as part of the assembly step. The unique substrate ID in combination with a unique design ID can instruct the production line machine to place only the needed components on each substrate in the panel. Utilizing the same die attach, same bonding wire, molding compound and solder ball materials, avoids changeover of materials in the pick and place machine. The substrate ID may be permanently added to the substrate by such methods as a laser marking it, by assigning pins on the system product to carry the substrate ID, or a register read by a microcontroller (uC) or microprocessor (uP) (if part of the system product). Therefore, a device may be selected by reading the device ID on the substrate regardless of the mix of SIPs presented to the marking machine. Laser marking of the substrate or final package can be selected by the ID on the substrate regardless of the mix of SIPs presented to the marking machine.

In certain embodiments, accommodation for the unique placement of die 1314 may be made from the super-set of devices (from many system devices included in the production batch) and can be accomplished through several means, such as, but not limited to, multiple die in a carrier (also known as a waffle pack), or several full or partial wafers stacked in a handling system in the die attach machine. Common assembly process parameters being a goal, the wire bonding layout can be selected during design stage 101 or planning stage 102 so that multiple wire lengths and number of wires can be used during the assembly stage 104. Similarly, a super set of passive devices may be made available in multiple reels at a pick and place machine and the machine picks up the necessary passive devices 1312 for each particular system SiP device. For example, instead of having capacitors of any value used in the design, the capacitors will have preselected values, like for example, but not limited to, 1 microfarad, 0.1 microfarad, 0.001 microfarad, etc. Similarly, for resistors and other types of passive components only limited preselected values would be used in the design and available for pick and place. Similarly for active devices, like OpAmps, A/Ds, processors, and memories, limited preselected die for these devices would be selected and available in reels (or otherwise) for use in a design.

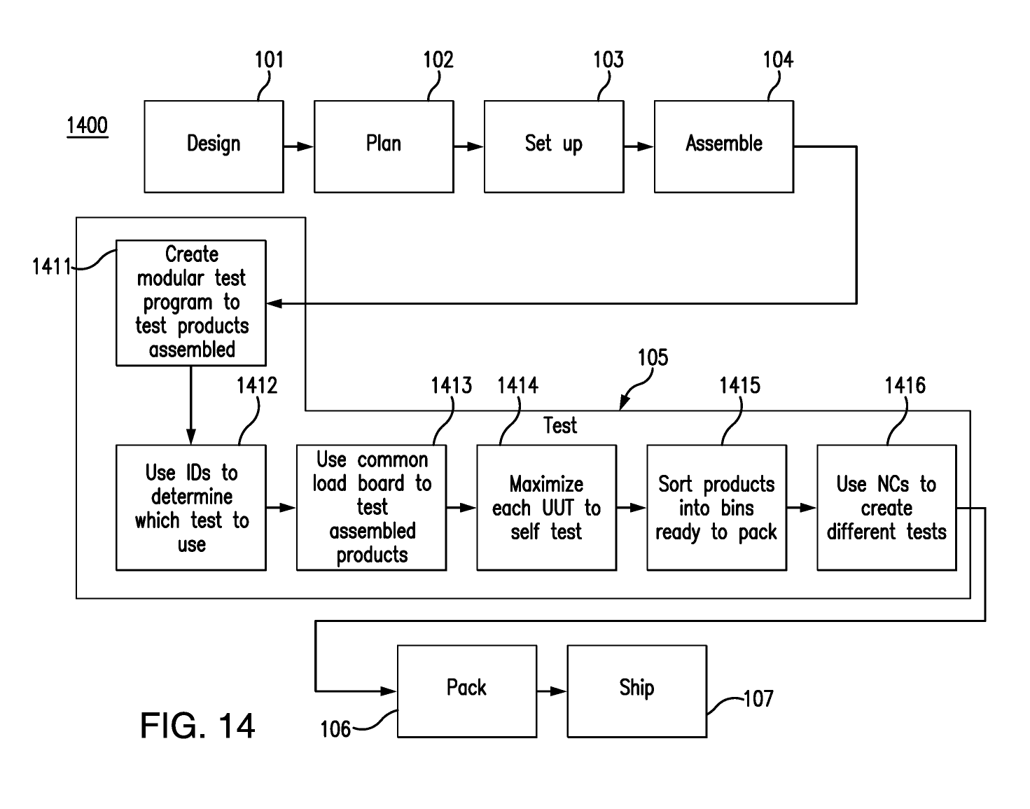

Referring now to FIG. 14, a test step 1400 according to some embodiments is provided. This step may correspond, for instance, to step 105 of FIG. 1. In this example, once the design 101, plan 102, setup 103 and assembly step 104 are completed the test step 105 begins on the packaged parts. According to some embodiments, the test step 1400 uses the same tester platform for all of the Units Under Test (UUT) and which were assembled in the previous step. For instance, a modular test program 1411 is used which alters how a UUT is tested based on its design ID 1412. In some instances, a common load board is used 1413 for all of the UUTs with the same physical dimensions. The load board may have a super set of power supply and signal pins of which are selectable by the test program. The Test step 1400 may use self-test capabilities 1414 if the UUT is capable of doing so. The Test step may also use the same handler 1415 with at least n+1 bins where there are n bins for good system products and one bin for bad units. Additional bins may be used if further sorting is needed for multiple failure modes or multiple shipping locations for any one system product. Finally, the tester may use No Connect (NC) pins on the packaged devices of each of the products or devices from the Design step 101 to create additional test capability as determined in the plan 102, set up 103 and assemble 104 steps. Any use of NC pins for testing purposes means those pins are not considered part of the pins needed for normal product operation, and are connected to test features inside the product and are only useful for test purposes. These aspects of the test step 1400 can eliminate the need for unique test platforms, load boards, test programs and handlers for each of the unique devices in the lot to be tested. Once the devices have been tested and passed the good electrical devices for each of the unique product designs are ready for packing 106 and shipping 107.

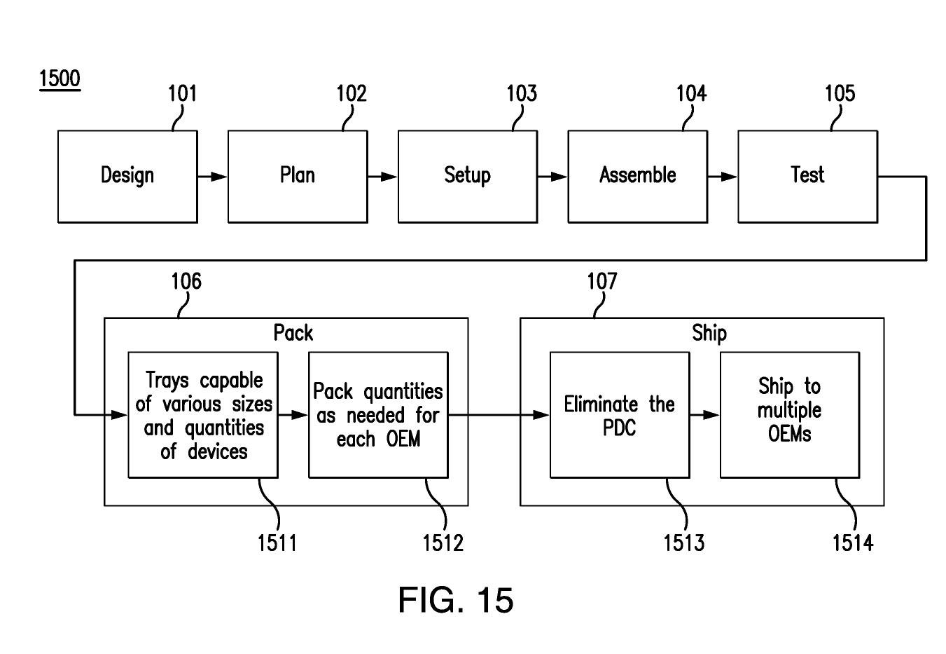

Referring now to FIG. 15, FIG. 15 depicts pack and ship steps 1500 according to some embodiments. This may correspond, for instance, to steps 106 and 107 of FIG. 1. In this example, once the multiple different devices from the assembly step 104 are tested 105, the resulting good electrical devices are packed 106 and shipped 107 to the OEM or customer. The trays used to bin the good devices in the test step are transferred to shipping trays designed for various package sizes and quantities 1511 in pack quantities needed for each OEM 1512 or customer. The packaging 106 and shipping 107 steps may be optimized for large or small batch sizes by incorporating the function of the PDC 1513 into two steps.

According to some embodiments, the first step is to integrate any quality control checks of the final device. The individual devices may need to be inspected for flaws before they are packed and shipped. These tests can be integrated into the test sequence by adding high speed multi-spectrum cameras that analyze the devices as they are packed in and removed from the test board. The quality decision is made through algorithms that visually inspect the devices. The decision is then relayed back to the handler that either continues normal binning if QC passes or places the device in a QC failed bin if QC comes back as failed.

Once the device is deemed acceptable from an electrical and QC perspective, it can be packaged for shipment to the customer, for instance, to fulfill an order 1512. This may require the order fulfillment system to communicate with the tester and handler. In certain aspects, the tester/handler needs to identify the current device it is working on using data in the order fulfillment system and based on a unique product or device ID. The order fulfilment system needs to tell the tester/handler that the device, if good, needs to go to a specific order/tray. The handler knows where the tray for that order is located and deposits the tested and QC′ed device in the correct tray. If the tray is full or the order is completed, the order fulfillment system signals the handler to move the tray to the sealing and labeling station. If the order is not complete or the tray is not full, then the tray is held over until the next needed device is tested. Since the handler can only handle a set number of trays at one time it now requires a system to hold “in progress” trays while the tester works on other trays until it is time to service the previous tray again. This handler machine has racks to store trays and small conveyer belts to move the tray in and out of the handler and the shelves. It has a conveyer belt arm that moves up and down and left and right to align the tray with the appropriate shelf. This system is controlled by the tester, order fulfillment system, and process management system. Use of standardized trays may also cause problems for the customized system embodiments that are described herein. Standard trays require every device in the tray to be the same size and every tray to have the same number of components in it. This requires different trays for every device increasing the size of the shipment and wasted space as some trays are shipped only partially filled. Instead a mix of standard trays and customized trays can be used to pack the order in the most efficient ways. An algorithm is used to figure out the optimal packing situation for the order. Then where possible standard trays will be used. When it is more optimal to using something else customized trays can be created to match the optimal packing through 3D printing processes. Customized trays give the ability to kit devices, having different types of devices of different sizes all in a single tray to be shipped. Giving customer flexibility on how they wish to receive their orders. After the trays/orders are completed and sent to the sealing and labeling station they are packed per order specification and shipped to the customer through commercially available services.

While various embodiments of the present disclosure are described herein, it should be understood that they have been presented by way of example only, and not limitation. Thus, the breadth and scope of the present disclosure should not be limited by any of the above-described exemplary embodiments. Moreover, any combination of the above-described elements in all possible variations thereof is encompassed by the disclosure unless otherwise indicated herein or otherwise clearly contradicted by context.

Additionally, while the processes described above and illustrated in the drawings are shown as a sequence of steps, this was done solely for the sake of illustration. Accordingly, it is contemplated that some steps may be added, some steps may be omitted, the order of the steps may be re-arranged, and some steps may be performed in parallel.

1. A method for manufacturing a plurality of System in Package, SiP, devices on a production line system, comprising:
assembling a first device of said plurality of SiP devices, wherein assembling said first device comprises:
arranging a first plurality of components on a first substrate according to a first design, wherein said first substrate has a first optical identifier on a surface of said first substrate, and
creating a first electrical identifier related to said first design; and
assembling a second device of said plurality of SiP devices, wherein assembling said second device comprises:
arranging a second plurality of components on a second substrate according to a second, different design, wherein said second substrate has a second optical identifier on a surface of said second substrate, and
creating a second electrical identifier related to said second design.

2. The method of claim 1, wherein said first and second substrates have an identical layout and said first and second optical identifiers are the same.

3. The method of claim 1, wherein said first and second substrates have a different layout from each other and said first and second optical identifiers are different from each other.

4. The method of claim 1, wherein said first and second substrates are part of a common panel.

5. The method of claim 1, wherein creating said first electrical identifier comprises placing one or more resistive elements, capacitive elements, or wire bonds on said first substrate, and creating said second electrical identifier comprises placing one or more resistive elements, capacitive elements, or wire bonds on said second substrate.

6. The method of claim 1, wherein at least one of said first and second optical identifier is formed by one or more resistive elements, capacitive elements, and wire bonds.

7. The method of claim 1, wherein assembling said first and second devices occurs in a single production run.

8. The method of claim 1, further comprising:
importing said first and second designs into one or more memories of said production line system, wherein said first imported design refers to said first optical identifier and said first electrical identifier and said second imported design refers to said second optical identifier and said second electrical identifier.

9. The method of claim 1, further comprising:
adjusting one or more settings of one or more machines in said production line system based at least in part on said first or second electrical identifier.

10. The method of claim 1, wherein said first and second substrates are selected from a set of standard substrates.

11. The method of claim 1, further comprising:
loading said first and second components together on said production line system, wherein said first set of components and said second components are selected from a single group of components;

12. The method of claim 1, further comprising:
loading said first and second substrates on said production line system, wherein each of said first and said second substrates is a common substrate for one or more families of devices.

13. A System in Package, SiP, device, comprising:
a substrate, wherein said substrate comprises an optical identifier for said substrate, on a surface of said substrate; and
a plurality of components arranged on said substrate to define an electrical identifier corresponding to said SiP device.

14. The device of claim 13, wherein at least one of said plurality of components is a SiP device.

15. The device of claim 13, wherein said electrical identifier corresponds to a unique design of said SiP device.

16. A production line system for manufacturing a plurality of System in Package, SiP, devices, comprising:
one or more memories of said production line system for storing at least a first design of a first of said plurality of SiP devices and at least a second design of a second of said plurality of SiP devices, such that said first and second designs are both contained in said one or memories of said production line system;
production line storage equipment, wherein said storage equipment is configured to store a set of preselected components on said production line system and to store first and second substrates on said production line system; and
one or more processors configured to control one or more machines of said production line system to assemble said first and second SiP devices in a single production run,
wherein said first design uses at least one component from said set of preselected components and said first substrate, and said second design uses at least one component from said set of preselected components and said second substrate.

17. The production line system of claim 16, wherein said one or more processors are further configured read one or more electrical identifiers corresponding to said first and second designs and control said production line to assemble said first and second SiP devices according to said electrical identifiers.

18. The production line system of claim 16, wherein said plurality of SiP device designs use only components and substrates from the sets of preselected components and substrates.

19. The production line system of claim 16, further comprising:
one or more pieces of equipment programmed to automatically adjust its settings to perform unique activities needed for each substrate based on a unique identifier for each of said substrates in conjunction with said design when said substrate is loaded on each said piece of equipment.
